(19) United States
(12) Patent Application Publication
(10) Pub. No.: US 2025/0056954 A1
(43) Pub. Date: Feb. 13, 2025

(54) DISPLAY DEVICE AND MANUFACTURING METHOD OF DISPLAY DEVICE

(71) Applicant: Samsung Display Co., LTD., Yongin-si (KR)

(72) Inventor: Tae Gyun KIM, Yongin-si (KR)

(21) Appl. No.: 18/751,076

(22) Filed: Jun. 21, 2024

(30) Foreign Application Priority Data
Aug. 9, 2023 (KR) 10-2023-0103973

(51) Int. Cl. H01L 27/15

(52) U.S. Cl. CPC H01L 27/156

(57) ABSTRACT

A display device includes a first base layer, a circuit layer above the first base layer, a silicon substrate above the circuit layer, a light-emitting element above the silicon substrate, and electrically connected to the circuit layer through an opening defined by the silicon substrate, and a second base layer above the silicon substrate and the light-emitting element.

### CROSS-REFERENCE TO RELATED APPLICATION

The present application claims priority to, and the benefit of, Korean Patent Application No. 10-2023-0103973, filed on Aug. 9, 2023, in the Korean Intellectual Property Office, the entire disclosure of which is incorporated herein by reference.

### BACKGROUND

### 1. Field

The present disclosure relates to a display device, and to a manufacturing method thereof.

### 2. Description of the Related Art

Recently, as interest in information display is increasing, research and development on display devices are continuously made.

### SUMMARY

The present disclosure provides a display device, and a manufacturing method of the display device, which can reduce manufacturing costs and simplify the process.

The aspects of the present disclosure are not limited to the aforesaid, but other aspects not described herein will be clearly understood by those skilled in the art from descriptions below.

A display device according to one or more embodiments includes a first base layer, a circuit layer above the first base layer, a silicon substrate above the circuit layer, a light-emitting element above the silicon substrate, and electrically connected to the circuit layer through an opening defined by the silicon substrate, and a second base layer above the silicon substrate and the light-emitting element.

A thickness of the first base layer may be greater than a thickness of the silicon substrate.

The thickness of the first base layer may be greater than a thickness of the second base layer.

The second base layer may include a transparent inorganic material.

The first base layer and the second base layer may include a same material.

The light-emitting element may include a first semiconductor layer above the silicon substrate, an active layer above the first semiconductor layer, and a second semiconductor layer above the active layer.

The display device may further include an electrode layer above the second semiconductor layer, and covered by the second base layer.

The display device may further include an electrode layer above the second semiconductor layer, and exposed by the second base layer.

An opening defined by the silicon substrate may expose the first semiconductor layer.

A manufacturing method of a display device according to one or more embodiments includes forming a light-emitting element above a first surface of a silicon substrate, forming a first inorganic layer above the first surface of the silicon substrate and the light-emitting element, grinding a second surface of the silicon substrate, forming an opening by etching the silicon substrate, forming a circuit layer above the second surface of the silicon substrate and the light-emitting element, and forming a second inorganic layer above the circuit layer.

The opening of the silicon substrate may expose the light-emitting element.

The circuit layer may contact the light-emitting element through the opening of the silicon substrate.

A thickness of the silicon substrate may be less than a thickness of the second inorganic layer.

The manufacturing method may further include grinding the first inorganic layer.

A thickness of the first inorganic layer may be less than the thickness of the second inorganic layer.

The first inorganic layer and the second inorganic layer may include a same material.

A manufacturing method of a display device according to one or more embodiments includes forming a light-emitting element layer above a first silicon substrate, forming a second silicon substrate above the light-emitting element layer, forming an opening by etching the second silicon substrate, forming a circuit layer above the second silicon substrate and the light-emitting element layer, forming an inorganic layer above the circuit layer, removing the first silicon substrate, and forming a light-emitting element by etching the light-emitting element layer.

The opening of the second silicon substrate may expose the light-emitting element layer.

The circuit layer may contact the light-emitting element layer through the opening of the second silicon substrate.

A thickness of the second silicon substrate may be less than a thickness of the inorganic layer.

Specific details of other embodiments are included in specification and drawings.

According to the above-described embodiments, the light-emitting element and the circuit layer can be formed using both surfaces of the silicon substrate, and the light-emitting element and the circuit layer can be electrically connected through the opening of the silicon substrate. Accordingly, a bonding process for combining the light-emitting element and the circuit layer can be omitted, thereby reducing costs, and simplifying the process.

Aspects according to embodiments are not limited by contents described above, and more various aspects are included in the present specification.

### BRIEF DESCRIPTION OF DRAWINGS

FIG. 1 is a plan view illustrating a display device according to one or more embodiments.

FIG. 2 is a circuit diagram of a pixel according to one or more embodiments.

FIGS. 3 to 6 are cross-sectional views of a display device according to one or more embodiments.

FIGS. 7 to 17 are cross-sectional views illustrating process steps of a manufacturing method of a display device according to one or more embodiments.

FIGS. 18 to 24 are cross-sectional views illustrating process steps of a manufacturing method a display device according to one or more embodiments.

FIGS. 25 to 32 are cross-sectional views illustrating process steps of a manufacturing method a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second objects, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the X-axis, the Y-axis, and/or the Z-axis are not limited to three axes of a rectangular coordinate system, and may be interpreted in a broader sense. For example, the X-axis, the Y-axis, and the Z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

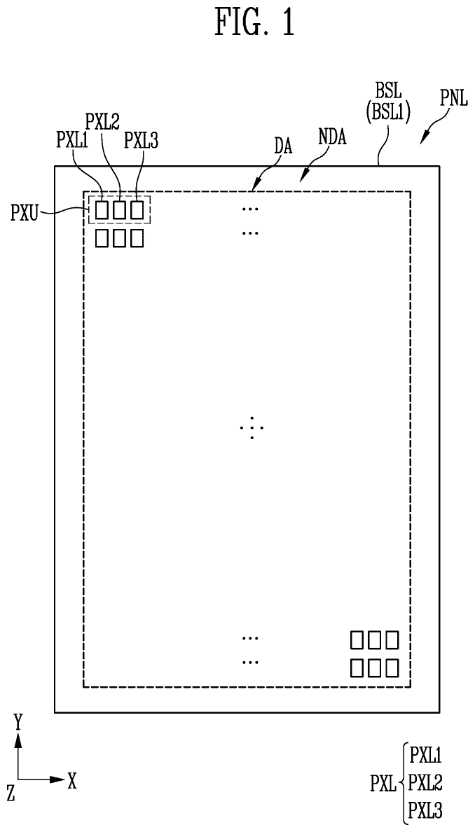

FIG. 1 is a plan view illustrating a display device according to one or more embodiments.

FIG. 1 illustrates a display device that can use a light-emitting element as a light source, for example, a display panel PNL provided in the display device.

For convenience of description, a structure of the display panel PNL will be briefly illustrated centering on the display area DA in FIG. 1. However, at least one driving circuit (e.g., at least one of a scan driver and a data driver), lines, and/or pads, may be further located in the display panel PNL according to the present disclosure.

Referring to FIG. 1, the display panel PNL is defined in a plane defined by a X-axis and a Y-axis, and may include a base layer BSL (or first base layer BSL1) and a pixel PXU located on the base layer BSL. The pixel PXU may include first pixels PXL1, second pixels PXL2, and/or third pixels PXL3. Hereinafter, when at least one of the first pixels PXL1, the second pixels PXL2, and the third pixels PXL3 is arbitrarily referred to, or when two or more types of pixels are collectively referred to, it will be referred to as “pixel PXL” or “pixels PXL.”

The base layer BSL (or first base layer BSL1) may constitute a base member of the display panel PNL, and may serve as a substrate. For example, the base layer BSL may be formed of an inorganic layer. The base layer BSL may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto.

The display panel PNL, and the base layer BSL for forming the display panel PNL, may include a display area DA for displaying an image, and a non-display area NDA excluding the display area DA. The pixels PXL may be located in the display area DA. Various lines, pads, and/or built-in circuits connected to the pixels PXL of the display area DA may be located in the non-display area NDA. The pixels PXL may be regularly arranged according to a stripe or PENTILE™ arrangement structure (PENTILE™ being a registered trademark of Samsung Display Co., Ltd., Republic of Korea). However, an arrangement of the pixels PXL is not limited thereto, and the pixels PXL may be arranged in the display area DA in various structures and/or ways.

According to one or more embodiments, two or more types of pixels PXL for emitting light of different colors may be located in the display area DA. For example, first pixels PXL1 for emitting light of a first color, second pixels PXL2 for emitting light of a second color, and third pixels PXL3 for emitting light of a third color may be arranged in the display area DA. At least one of the first to third pixels PXL1, PXL2, and PXL3 located adjacent to each other may constitute one pixel PXU capable of emitting light of various colors. For example, each of the first to third pixels PXL1, PXL2, and PXL3 may be a sub-pixel for emitting light of a color (e.g., predetermined color). According to embodiments, the first pixel PXL1 may be a red pixel for emitting red light, the second pixel PXL2 may be a green pixel for emitting green light, and the third pixel PXL3 may be a blue pixel for emitting blue light, but is not limited thereto.

In one or more embodiments, each of the first pixel PXL1, the second pixel PXL2, and the third pixel PXL3 may include light-emitting elements LD for emitting light of the same color as each other, and may include the color conversion layer and/or the color filter layer of different colors, located on each of the light-emitting elements LD, thereby emitting light of the first color, the second color, and the third color, respectively. In one or more other embodiments, the first pixel PXL1, the second pixel PXL2, and the third pixel PXL3 may use the light-emitting element of the first color, the light-emitting element of the second color, and the light-emitting element of the third color as light sources, respectively, thereby emitting light of the first color, the second color and the third color, respectively. However, the color, type, and/or number of pixels PXL constituting each pixel PXU are not particularly limited. That is, the color of light emitted from each pixel PXL may be variously changed.

The pixel PXL may include at least one light source driven by a control signal (e.g., predetermined control signal, such as a scan signal and/or a data signal) and/or a power supply (e.g., predetermined power supply, such as a first power supply and a second power supply). In one or more embodiments, the light source may include ultra-small light-emitting elements having a size of several nanometers to several micrometers. However, the present disclosure is not necessarily limited thereto, and various types of light-emitting elements may be used as the light source of the pixel PXL.

In one or more embodiments, each pixel PXL may be formed of active pixels. However, the type, structure, and/or driving method of the pixels PXL applicable to the display device is not particularly limited. For example, each pixel PXL may be made of a pixel of a passive or active light-emitting display device having various structures and/or driving methods.

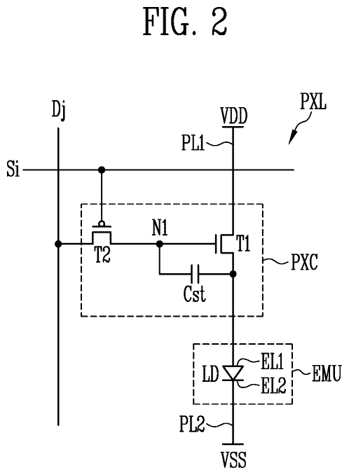

FIG. 2 is a circuit diagram of a pixel according to one or more embodiments.

FIG. 2 illustrates an electrical connection relationship between constituent elements included in a pixel PXL that can be applied to an active display device. However, the types of constituent elements included in the pixel PXL are not necessarily limited thereto.

According to one or more embodiments, the pixel PXL illustrated in FIG. 2 may be any one of the first pixel PXL1, the second pixel PXL2, and the third pixel PXL3 provided in the display panel PNL of FIG. 1. The first pixel PXL1, the second pixel PXL2, and the third pixel PXL3 may have substantially the same or similar structure to each other.

Referring to FIG. 2, each pixel PXL may include a light-emitting unit EMU that generates light having luminance corresponding to a data signal. Also, the pixel PXL may further include a pixel circuit PXC for driving the light-emitting unit EMU.

According to one or more embodiments, the light-emitting unit EMU may include at least one light-emitting element LD electrically connected between a first power line PL1 to which a voltage of a first driving power supply VDD is applied, and a second power line PL2 to which a voltage of a second driving power supply VSS is applied. For example, the light-emitting unit EMU may include a first electrode EL1 connected to the first driving power supply VDD through a pixel circuit PXC and the first power line PL1, a second electrode EL2 connected to the second driving power supply VSS through the second power line PL2, and a light-emitting element LD connected between the first electrode EL1 and the second electrode EL2. In one or more embodiments, the first electrode EL1 may be an anode, and the second electrode EL2 may be a cathode.

The light-emitting element LD may include one end connected to the first driving power supply VDD and the other end connected to the second driving power supply VSS. In embodiments, one end of the light-emitting element LD may be provided integrally with the first electrode EL1 to be connected to the first electrode EL1, and the other end of the light-emitting element LD may be provided integrally with the second electrode EL2 to be connected to the second electrode EL2. The first driving power supply VDD and the second driving power supply VSS may have different potentials from each other. In this case, a potential difference between the first and second driving power supplies VDD and VSS may be set to be greater than or equal to a threshold voltage of the light-emitting element LD during the light-emitting period of the pixel PXL.

The light-emitting element LD may constitute an effective light source of the light-emitting unit EMU. The light-emitting element LD may emit light with a luminance corresponding to a driving current supplied through the pixel circuit PXC. For example, during each frame period, the pixel circuit PXC may supply a driving current corresponding to a grayscale value of corresponding frame data to the light-emitting unit EMU. The driving current supplied to the light-emitting unit EMU may flow through the light-emitting element LD. Accordingly, while the light-emitting element LD emits light with luminance corresponding to the driving current, and the light-emitting unit EMU may emit light.

The pixel circuit PXC may be connected to the scan line (e.g., an i-th scan line Si) and the data line (e.g., a j-th data line Dj) of the pixel PXL. For example, when the pixel PXL is located at the i-th row (i is positive integer) and the j-th column (j is positive integer) of the display area DA, the pixel circuit PXC of the pixel PXL may be connected to the i-th scan line Si and the j-th data line Dj of the display area DA. According to one or more embodiments, the pixel circuit PXC may include first and second transistors T1 and T2 and a storage capacitor Cst. However, the structure of the pixel circuit PXC is not limited to the embodiments corresponding to FIG. 2.

A first terminal of the first transistor T1 (driving transistor) may be connected to the first driving power supply VDD, and a second terminal thereof may be electrically connected to the light-emitting element LD. A gate electrode of the first transistor T1 may be connected to a first node N1. The first transistor T1 may control an amount of the driving current supplied to the light-emitting elements LD in response to the voltage of the first node N1.

A first terminal of the second transistor T2 (e.g., switching transistor) may be connected to the j-th data line Dj, and the second terminal thereof may be connected to the first node N1. Here, the first terminal and the second terminal of the second transistor T2 may be different terminals. For example, when the first terminal is a source electrode, the second terminal may be a drain electrode. The gate electrode of the second transistor T2 may be connected to the i-th scan line Si.

The second transistor T2 may be turned on when a scan signal of a voltage at which the second transistor T2 can be turned on is supplied from the i-th scan line Si, and may electrically connect the j-th data line Dj and the first node N1. The data signal of the corresponding frame may be supplied to the data line Dj, and thus the data signal may be transferred to the first node N1. The data signal transferred to the first node N1 may be charged in the storage capacitor Cst.

The storage capacitor Cst may charge a voltage corresponding to the data signal supplied to the first node N1, and may maintain the charged voltage until the data signal of the next frame is supplied.

In FIG. 2, the pixel circuit PXC is shown including the second transistor T2 for transferring the data signal into the pixel PXL, a storage capacitor Cst for storing the data signal, and the first transistor T1 for supplying a driving current corresponding to the data signal to the light-emitting element LD, but the present disclosure is not limited thereto, and the structure of the pixel circuit PXC may be variously changed. For example, the pixel circuit PXC may further include at least one transistor element, such as a transistor element for compensating for the threshold voltage of the first transistor T1, a transistor element for initializing the first node N1, and/or a transistor element for controlling the light-emitting time of the light-emitting element LD, and the like, or other circuit elements, such as a boosting capacitor for boosting a voltage of the first node N1, and the like.

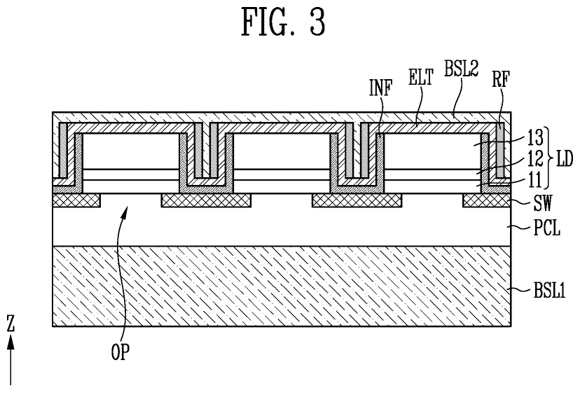

FIGS. 3 to 6 are cross-sectional views of a display device according to one or more embodiments.

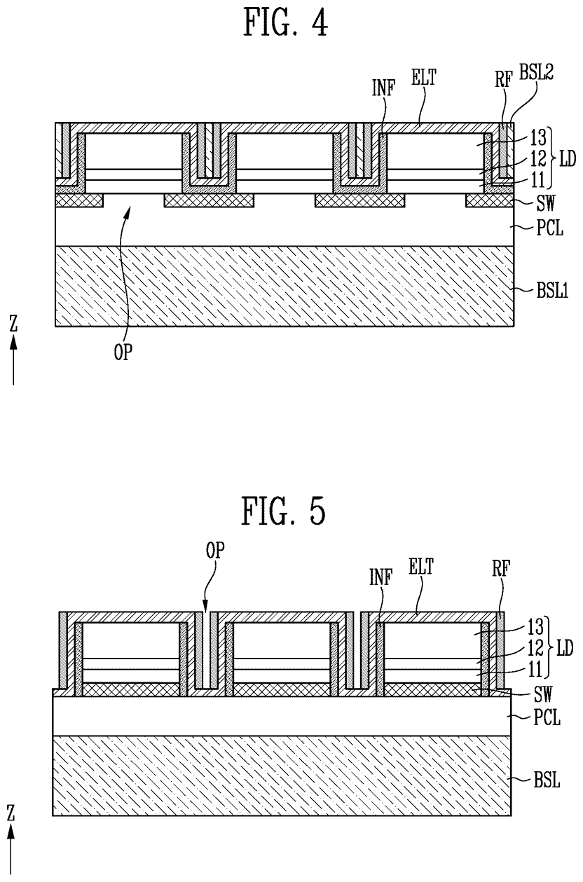

Referring to FIGS. 3 and 4, a circuit layer PCL may be located on the first base layer BSL1. The first base layer BSL1 may be formed of an inorganic layer. The first base layer BSL1 may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The first base layer BSL1 may be formed to have a thickness of hundreds of microns, but is not necessarily limited thereto.

The circuit layer PCL may include circuit elements including transistors that constitute the pixel circuit (PXC in FIG. 2) of each pixel PXL. For example, the circuit layer PCL may be formed of CMOS, which is a combination of NMOS and PMOS, but is not necessarily limited thereto.

A silicon substrate SW may be located on the circuit layer PCL. The silicon substrate SW may include a single crystalline silicon wafer, a polycrystalline silicon wafer, or an amorphous silicon wafer. A thickness of the silicon substrate SW may be thinner than a thickness of the first base layer BSL1. For example, the silicon substrate SW may be formed to have a thickness of several microns but is not necessarily limited thereto.

The silicon substrate SW may include/define an opening OP. The opening OP of the silicon substrate SW may expose the light-emitting element LD (or first semiconductor layer 11). The circuit layer PCL may be electrically connected to the light-emitting element LD (or first semiconductor layer 11) through the opening OP of the silicon substrate SW. The circuit layer PCL may directly contact the light-emitting element LD (or the first semiconductor layer 11) through the opening OP of the silicon substrate SW.

Light-emitting elements LD may be located on the silicon substrate SW. In one or more embodiments, the light-emitting elements LD may be structures manufactured by stacking or growing on the silicon substrate SW, and may be directly located on the silicon substrate SW. The light-emitting elements LD may be provided on the silicon substrate SW with a shape extending from the silicon substrate SW in the third direction (Z-axis direction). The light-emitting elements LD may be light-emitting diodes (LED) manufactured with ultra-small size to have a diameter and/or length of several nanometers to several micrometers. However, the present disclosure is not necessarily limited thereto, and the size of the light-emitting element LD may be variously changed to meet requirements (or design conditions) of a lighting device or a display device to which the light-emitting element LD is applied.

Each of the light-emitting elements LD may include a first semiconductor layer 11, an active layer 12, and/or a second semiconductor layer 13.

The first semiconductor layer 11 may be a semiconductor layer of a first conductivity type. For example, the first semiconductor layer 11 may include a p-type semiconductor layer. For example, the first semiconductor layer 11 may include at least one semiconductor material selected from InAlGaN, GaN, AlGaN, InGaN, and AlN, and may include a p-type semiconductor layer doped with a first conductive dopant, such as Mg, and the like. However, the material constituting the first semiconductor layer 11 is not limited thereto, and various other materials may constitute the first semiconductor layer 11.

The active layer 12 may be located between the first semiconductor layer 11 and the second semiconductor layer 13. The active layer 12 may include any one of a single well structure, a multi well structure, a single quantum well structure, a multi quantum well (MQW) structure, a quantum dot structure, or a quantum wire structure, but is limited thereto. The active layer 12 may include GaN, InGaN, InAlGaN, AlGaN, or AlN, and various other materials may constitute the active layer 12.

When a voltage of a threshold voltage or more is applied to opposite ends of the light-emitting element LD, the light-emitting element LD emits light while electron-hole pairs are recombined in the active layer 12. The light-emitting element LD may be used as a light source of various light-emitting elements including the pixel of the display device by controlling light-emitting of light-emitting element LD using this principle.

The second semiconductor layer 13 may be located on the active layer 12 and may include a semiconductor layer of a different type from the first semiconductor layer 11. The second semiconductor layer 13 may include an n-type semiconductor layer. For example, the second semiconductor layer 13 may include at least one semiconductor material selected from InAlGaN, GaN, AlGaN, InGaN, and AlN, and may include an n-type semiconductor layer doped with a second conductive dopant, such as Si, Ge, Sn, and the like. However, the material constituting the second semiconductor layer 13 is not limited thereto, and the second semiconductor layer 13 may be formed of various materials.

An insulating film INF may be provided on a surface of the light-emitting element LD. The insulating film INF may at least partially surround the first semiconductor layer 11, the active layer 12, and/or the second semiconductor layer 13. For example, the insulating film INF may be partially located on a side surface of the light-emitting element LD. The insulating film INF may expose one surface of the first semiconductor layer 11 and/or one surface of the second semiconductor layer 13 of the light-emitting element LD. The insulating film INF can reduce or prevent the likelihood of an electrical short that may occur when the active layer 12 contacts a conductive material other than the first and second semiconductor layers 11 and 13. The insulating film INF can improve lifespan and luminous efficiency of the light-emitting elements LD by reducing or minimizing surface defects of the light-emitting elements LD.

The insulating film INF may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

An electrode layer ELT may be located on the light-emitting element LD and/or the insulating film INF. The electrode layer ELT may be located on the second semiconductor layer 13 of the light-emitting element LD exposed by the insulating film INF. The electrode layer ELT may be electrically connected to the light-emitting element LD (or second semiconductor layer 13) exposed by the insulating film INF. The electrode layer ELT may directly contact the light-emitting element LD (or second semiconductor layer 13) exposed by the insulating film INF.

The electrode layer ELT may include transparent metal or transparent metal oxide. For example, the electrode layer ELT may include at least one of indium tin oxide (ITO), indium zinc oxide (IZO), and zinc tin oxide (ZTO), but is not limited thereto. As such, when the electrode layer ELT is made of transparent metal or transparent metal oxide, the light generated in the active layer 12 of the light-emitting element LD may pass through the electrode layer ELT and may be emitted to the outside of the light-emitting element LD.

According to one or more embodiments, a reflective layer RF may be further located on the electrode layer ELT. The reflective layer RF may be located on the side surface of the light-emitting element LD and/or the side surface of the electrode layer ELT, and may expose the upper surface of the light-emitting element LD and/or the upper surface of the electrode layer ELT. The reflective layer RF may reflect light emitted from the light-emitting element LD and guide it in the third direction (e.g., Z-axis direction), that is, in a front direction of the display panel PNL, thereby improving light-output efficiency. The material of the reflective layer RF is not particularly limited, and may include various reflective materials.

A second base layer BSL2 may be located on the light-emitting element LD, the electrode layer ELT, and/or the reflective layer RF. As shown in FIG. 3, the second base layer BSL2 may be provided between the light-emitting elements LD and on the light-emitting elements LD. For example, the second base layer BSL2 may cover the electrode layer ELT and/or the reflection layer RF. The second base layer BSL2 may be located on the reflective layer RF located between the light-emitting elements LD. The second base layer BSL2 may be directly located on the reflective layer RF located between the light-emitting elements LD, but is not necessarily limited thereto. The second base layer BSL2 may be located on the upper surface of the electrode layer ELT exposed by the reflective layer RF. The second base layer BSL2 may be located directly on the upper surface of the electrode layer ELT exposed by the reflection layer RF, but is not necessarily limited thereto.

A thickness of the second base layer BSL2 may be thinner than a thickness of the first base layer BSL1. For example, the second base layer BSL2 may be formed to have a thickness of around several microns, but is not necessarily limited thereto. Here, the thickness of the second base layer BSL2 may refer to a distance from the upper surface of the light-emitting element LD (or electrode layer ELT) to the upper surface of the second base layer BSL2.

As shown in FIG. 4, the second base layer BSL2 may be provided between the light-emitting elements LD. For example, the second base layer BSL2 may cover the reflective layer RF located between the light-emitting elements LD. The second base layer BSL2 may be directly located on the reflective layer RF located between the light-emitting elements LD. The second base layer BSL2 may expose the electrode layer ELT exposed by the reflective layer RF.

The second base layer BSL2 may be formed of an inorganic layer. For example, the second base layer BSL2 may include a transparent inorganic material. As such, when the second base layer BSL2 is made of a transparent inorganic material, the light generated in the active layer 12 of the light-emitting element LD may pass through the electrode layer ELT, and may be emitted to the outside of the light-emitting element LD. The second base layer BSL2 may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The second base layer BSL2 may include the same material as the above-described first base layer BSL1, but is not necessarily limited thereto.

According to the above, the light-emitting element LD and the circuit layer PCL may be formed using both surfaces of the silicon substrate SW. The light-emitting element LD and the circuit layer PCL may be electrically connected through the opening OP of the silicon substrate SW. Accordingly, a bonding process for combining the light-emitting element LD and the circuit layer PCL can be omitted, thereby reducing costs, and simplifying the process.

Referring to FIG. 5, a circuit layer PCL may be located on the base layer BSL. The base layer BSL may be formed of an inorganic layer. The base layer BSL may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The base layer BSL may be formed to have a thickness of hundreds of microns, but is not necessarily limited thereto.

The circuit layer PCL may include circuit elements including transistors that constitute the pixel circuit (PXC in FIG. 2) of each pixel PXL. For example, the circuit layer PCL may be formed of CMOS, which is a combination of NMOS and PMOS, but is not necessarily limited thereto.

A silicon substrate SW may be located on the circuit layer PCL. The silicon substrate SW may include a single crystalline silicon wafer, a polycrystalline silicon wafer, or an amorphous silicon wafer. A thickness of the silicon substrate SW may be thinner than a thickness of the base layer BSL. For example, the silicon substrate SW may be formed to have a thickness of several microns, but is not necessarily limited thereto.

The silicon substrate SW may include/define an opening OP. The opening OP of the silicon substrate SW may expose the circuit layer PCL. Light-emitting elements LD may be located on the silicon substrate SW. In one or more embodiments, the light-emitting elements LD may be structures manufactured by stacking or growing on the silicon substrate SW, and may be directly located on the silicon substrate SW. The light-emitting elements LD may be provided on the silicon substrate SW with a shape extending from the silicon substrate SW in the third direction (Z-axis direction). A detailed description of the light-emitting element LD has been described with reference to FIGS. 3 and 4, so overlapping content will be omitted.

An insulating film INF may be provided on a surface of the light-emitting element LD. The insulating film INF may at least partially surround the first semiconductor layer 11, the active layer 12, and/or the second semiconductor layer 13. For example, the insulating film INF may be located on a side surface of the light-emitting element LD. The insulating film INF may expose one surface of the first semiconductor layer 11 and/or one surface of the second semiconductor layer 13 of the light-emitting element LD. The insulating film INF can reduce or prevent the likelihood of an electrical short that may occur when the active layer 12 contacts a conductive material other than the first and second semiconductor layers 11 and 13. The insulating film INF can improve lifespan and luminous efficiency of the light-emitting elements LD by reducing or minimizing surface defects of the light-emitting elements LD.

The insulating film INF may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

An electrode layer ELT may be located on the light-emitting element LD and/or the insulating film INF. The electrode layer ELT may be located on the second semiconductor layer 13 of the light-emitting element LD exposed by the insulating film INF. The electrode layer ELT may be electrically connected to the light-emitting element LD (or second semiconductor layer 13) exposed by the insulating film INF. The electrode layer ELT may directly contact the light-emitting element LD (or second semiconductor layer 13) exposed by the insulating film INF. The electrode layer ELT may be electrically connected to the circuit layer PCL through the opening OP of the silicon substrate SW. The electrode layer ELT may directly contact the circuit layer PCL through the opening OP of the silicon substrate SW.

The electrode layer ELT may include transparent metal or transparent metal oxide. For example, the electrode layer ELT may include at least one of indium tin oxide (ITO), indium zinc oxide (IZO), and zinc tin oxide (ZTO), but is not limited thereto. As such, when the electrode layer ELT is made of transparent metal or transparent metal oxide, the light generated in the active layer 12 of the light-emitting element LD may pass through the electrode layer ELT and may be emitted to the outside of the light-emitting element LD.

According to one or more embodiments, a reflective layer RF may be further located on the electrode layer ELT. The reflective layer RF may be located on the side surface of the light-emitting element LD and/or the side surface of the electrode layer ELT, and may expose the upper surface of the light-emitting element LD and/or the upper surface of the electrode layer ELT. The reflective layer RF may reflect light emitted from the light-emitting element LD and guide it in the third direction (e.g., Z-axis direction), that is, in a front direction of the display panel PNL, thereby improving light-output efficiency. The material of the reflective layer RF is not particularly limited, and may include various reflective materials.

According to the above, the light-emitting element LD and the circuit layer PCL may be formed using both surfaces of the silicon substrate SW, and the light-emitting element LD and the circuit layer PCL may be electrically connected through the opening OP of the silicon substrate SW. Accordingly, as described above, a bonding process for combining the light-emitting element LD and the circuit layer PCL can be omitted, thereby reducing costs, and simplifying the process.

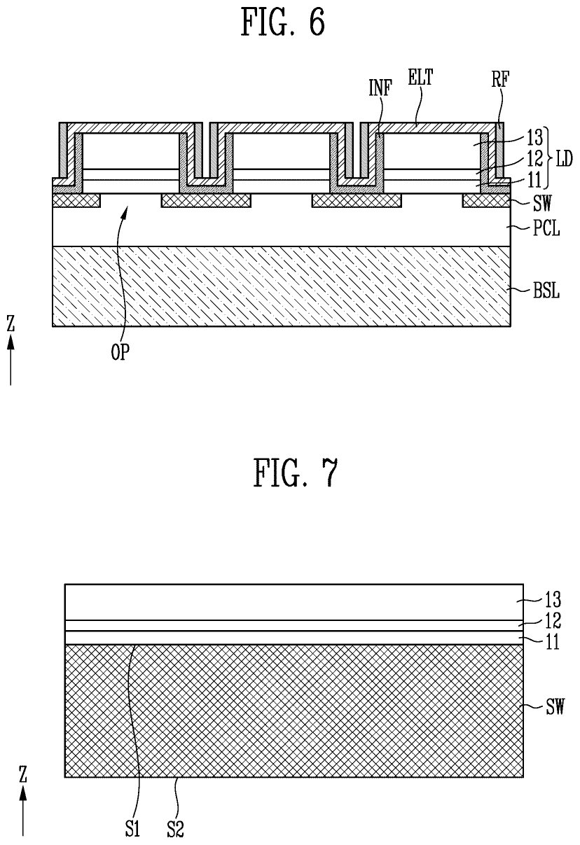

Referring to FIG. 6, a circuit layer PCL may be located on the base layer BSL. The base layer BSL may be formed of an inorganic layer. The base layer BSL may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The base layer BSL may be formed to have a thickness of hundreds of microns, but is not necessarily limited thereto.

The circuit layer PCL may include circuit elements including transistors that constitute the pixel circuit (PXC in FIG. 2) of each pixel PXL. For example, the circuit layer PCL may be formed of CMOS, which is a combination of NMOS and PMOS, but is not necessarily limited thereto.

A silicon substrate SW may be located on the circuit layer PCL. The silicon substrate SW may include a single crystalline silicon wafer, a polycrystalline silicon wafer, or an amorphous silicon wafer. A thickness of the silicon substrate SW may be thinner than a thickness of the base layer BSL. For example, the silicon substrate SW may be formed to have a thickness of several microns, but is not necessarily limited thereto.

The silicon substrate SW may include/define an opening OP. The opening OP of the silicon substrate SW may expose the light-emitting element LD (or first semiconductor layer 11). The circuit layer PCL may be electrically connected to the light-emitting element LD (or first semiconductor layer 11) through the opening OP of the silicon substrate SW. The circuit layer PCL may directly contact the light-emitting element LD (or the first semiconductor layer 11) through the opening OP of the silicon substrate SW.

Light-emitting elements LD may be located on the silicon substrate SW. In one or more embodiments, the light-emitting elements LD may be structures manufactured by stacking or growing on the silicon substrate SW and may be directly located on the silicon substrate SW. The light-emitting elements LD may be provided on the silicon substrate SW with a shape extending from the silicon substrate SW in the third direction (Z-axis direction). A detailed description of the light-emitting element LD has been described with reference to FIGS. 3 and 4, so overlapping content will be omitted.

An insulating film INF may be provided on a surface of the light-emitting element LD. The insulating film INF may at least partially surround the first semiconductor layer 11, the active layer 12, and/or the second semiconductor layer 13. For example, the insulating film INF may be located on a side surface of the light-emitting element LD. The insulating film INF may expose one surface of the first semiconductor layer 11 and/or one surface of the second semiconductor layer 13 of the light-emitting element LD. The insulating film INF can reduce or prevent the likelihood of an electrical short that may occur when the active layer 12 contacts a conductive material other than the first and second semiconductor layers 11 and 13. The insulating film INF can improve lifespan and luminous efficiency of the light-emitting elements LD by reducing or minimizing surface defects of the light-emitting elements LD.

The insulating film INF may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

An electrode layer ELT may be located on the light-emitting element LD and/or the insulating film INF. The electrode layer ELT may be located on the second semiconductor layer 13 of the light-emitting element LD exposed by the insulating film INF. The electrode layer ELT may be electrically connected to the light-emitting element LD (or second semiconductor layer 13) exposed by the insulating film INF. The electrode layer ELT may directly contact the light-emitting element LD (or second semiconductor layer 13) exposed by the insulating film INF. The electrode layer ELT may include transparent metal or transparent metal oxide. For example, the electrode layer ELT may include at least one of indium tin oxide (ITO), indium zinc oxide (IZO), and zinc tin oxide (ZTO), but is not limited thereto. As such, when the electrode layer ELT is made of transparent metal or transparent metal oxide, the light generated in the active layer 12 of the light-emitting element LD may pass through the electrode layer ELT, and may be emitted to the outside of the light-emitting element LD.

According to one or more embodiments, a reflective layer RF may be further located on the electrode layer ELT. The reflective layer RF may be located on the side surface of the light-emitting element LD and/or the side surface of the electrode layer ELT, and may expose the upper surface of the light-emitting element LD and/or the upper surface of the electrode layer ELT. The reflective layer RF may reflect light emitted from the light-emitting element LD and guide it in the third direction (e.g., Z-axis direction), that is, in a front direction of the display panel PNL, thereby improving light-output efficiency. The material of the reflective layer RF is not particularly limited, and may include various reflective materials.

According to the above, the light-emitting element LD and the circuit layer PCL may be formed using both surfaces of the silicon substrate SW, and the light-emitting element LD and the circuit layer PCL may be electrically connected through the opening OP of the silicon substrate SW. Accordingly, as described above, a bonding process for combining the light-emitting element LD and the circuit layer PCL can be omitted, thereby reducing costs and simplifying the process.

Subsequently, a manufacturing method of the display device according to the above-described embodiments will be described.

FIGS. 7 to 17 are cross-sectional views illustrating process steps of a manufacturing method of a display device according to one or more embodiments. FIGS. 7 to 17 are cross-sectional views for illustrating the manufacturing method of the display device of FIGS. 3 and 4, and are briefly shown and detailed symbols are omitted for convenience of description.

Referring to FIG. 7, first, a light-emitting element layer (first semiconductor layer 11, active layer 12, and second semiconductor layer 13) is formed on a first surface S1 of the silicon substrate SW. The silicon substrate SW may include a single crystalline silicon wafer, a polycrystalline silicon wafer, or an amorphous silicon wafer. The first semiconductor layer 11, the active layer 12, and the second semiconductor layer 13 may be sequentially formed in the third direction (Z-axis direction) on the first surface S1 of the silicon substrate SW. The first semiconductor layer 11, the active layer 12, and the second semiconductor layer 13 may be formed by growing a seed crystal by an epitaxial method. According to one or more embodiments, the first semiconductor layer 11, the active layer 12, and the second semiconductor layer 13 may be formed by metal organic chemical vapor deposition (MOCVD). However, the present disclosure is not necessarily limited thereto, and the first semiconductor layer 11, the active layer 12, and the second semiconductor layer 13 may be formed by various methods, such as electron beam deposition, physical vapor deposition (PVD), chemical vapor deposition (CVD), plasma laser deposition (PLD), dual-type thermal evaporation, sputtering, and the like. Because the first semiconductor layer 11, the active layer 12, and the second semiconductor layer 13 have been described with reference to FIGS. 3 and 4, redundant descriptions will be omitted.

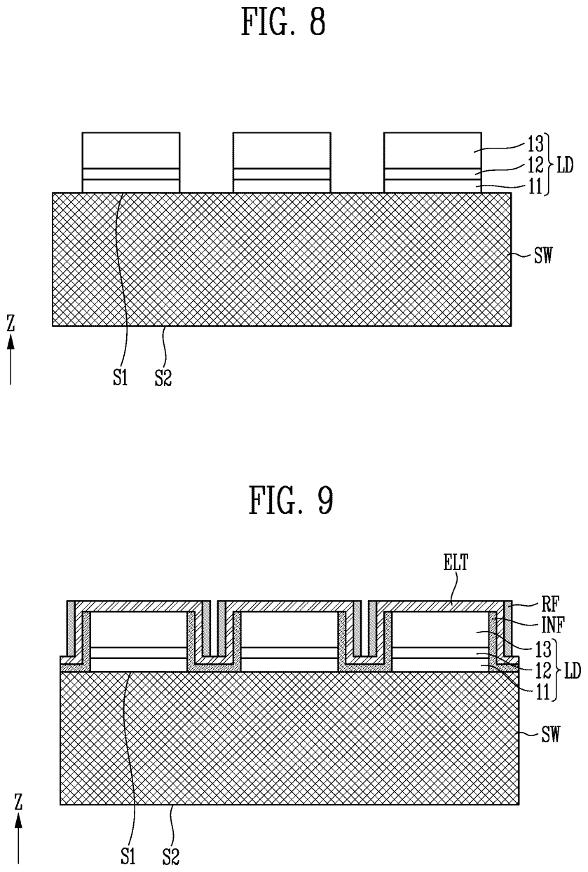

Referring to FIG. 8, the light-emitting element layer (e.g., first semiconductor layer 11, active layer 12, and second semiconductor layer 13) is then etched to a light-emitting element LD is formed on the first surface S1 of the silicon substrate SW. The etching process of the first semiconductor layer 11, the active layer 12, and the second semiconductor layer 13 is performed by dry etching, wet etching, reactive ion etching (RIE), inductively coupled plasma reactive ion etching (ICP-RIE), and the like, but is not necessarily limited thereto.

Referring to FIG. 9, an insulating film INF, an electrode layer ELT, and/or a reflective layer RF are then formed on the light-emitting element LD. The insulating film INF may be partially formed on the side surfaces of the light-emitting elements LD. For example, the insulating film INF may be formed on the entire surface of the silicon substrate SW, and then may be partially removed to expose the upper surface of the light-emitting elements LD.

The electrode layer ELT may be formed on the light-emitting element LD and the insulating film INF. The electrode layer ELT may be formed on the second semiconductor layer 13 of the light-emitting element LD exposed by the insulating film INF. The electrode layer ELT may directly contact the light-emitting element LD (or second semiconductor layer 13) exposed by the insulating film INF. The electrode layer ELT may be formed of transparent metal or transparent metal oxide. For example, the electrode layer ELT may be formed using at least one selected from indium tin oxide (ITO), indium zinc oxide (IZO), or zinc tin oxide (ZTO), but is not necessarily limited thereto.

According to one or more embodiments, a reflective layer RF may be further formed on the electrode layer ELT. The reflective layer RF may be partially formed on the side surface of the light-emitting element LD and/or the side surface of the electrode layer ELT. For example, the reflective layer RF may be formed on the entire surface of the silicon substrate SW and then partially removed to expose the upper surface of the light-emitting elements LD and/or the upper surface of the electrode layer ELT. The material of the reflective layer RF is not particularly limited and may be formed of various reflective materials.

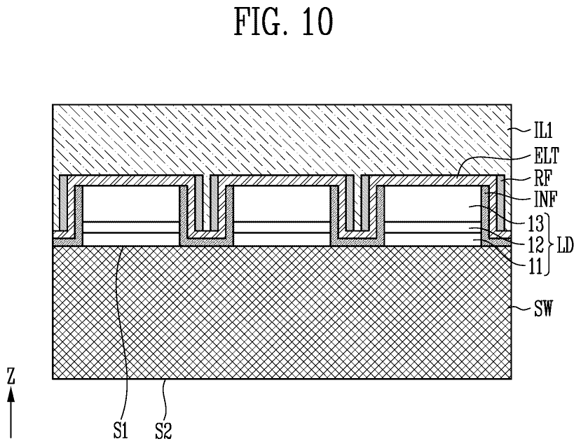

Referring to FIG. 10, a first inorganic layer IL1 is formed on the first surface S1 of the silicon substrate SW and on the light-emitting element LD. The first inorganic layer IL1 may cover the first surface S1 of the silicon substrate SW, and may cover the insulating film INF, the electrode layer ELT, and/or the reflection layer RF on the light-emitting element LD.

The first inorganic layer IL1 may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The first inorganic layer IL1 may be formed to have a thickness of hundreds of microns, but is not necessarily limited thereto.

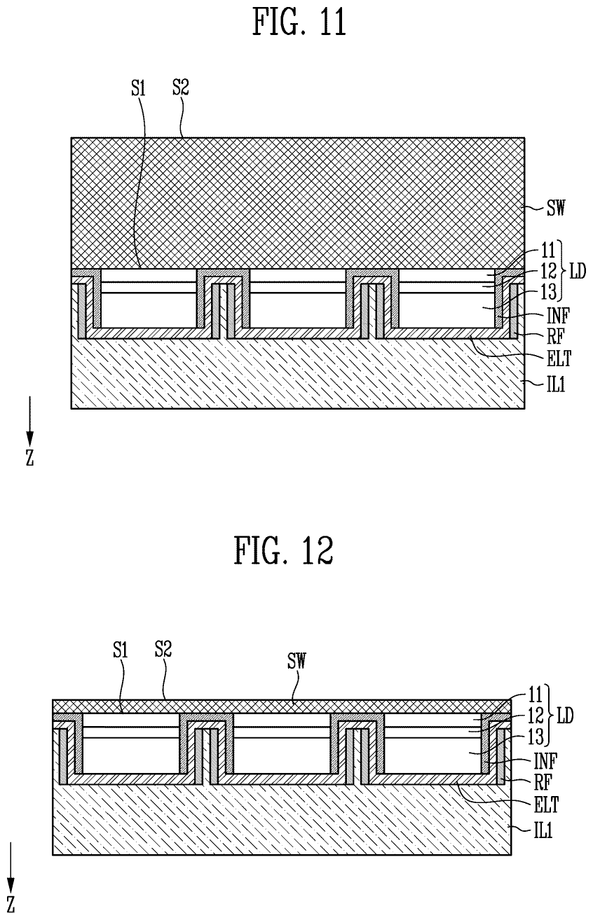

Referring to FIGS. 11 and 12, the silicon substrate SW and the first inorganic layer IL1 are then inverted, and the second surface S2 of the silicon substrate SW is ground down. The thickness of the silicon substrate SW may be ground to be thinner than the thickness of the first inorganic layer IL1. The silicon substrate SW may be formed to have a thickness of several microns, but is not necessarily limited thereto.

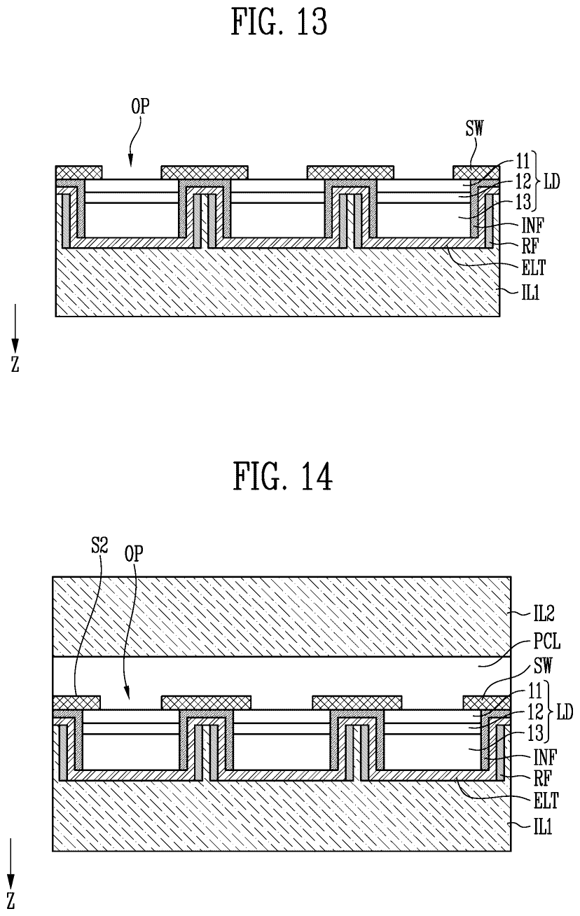

Referring to FIG. 13, the silicon substrate SW is then etched to form an opening OP. The opening OP of the silicon substrate SW may expose the light-emitting element LD (or first semiconductor layer 11).

Referring to FIG. 14, a circuit layer PCL and a second inorganic layer IL2 are then formed on the light-emitting element LD and the second surface S2 of the silicon substrate SW.

The circuit layer PCL may include circuit elements including transistors that constitute the pixel circuit (PXC in FIG. 2) of each pixel PXL. For example, the circuit layer PCL may be formed of CMOS, which is a combination of NMOS and PMOS, but is not necessarily limited thereto. The circuit layer PCL may be electrically connected to the light-emitting element LD (or first semiconductor layer 11) through the opening OP of the silicon substrate SW. The circuit layer PCL may directly contact the light-emitting element LD (or the first semiconductor layer 11) through the opening OP of the silicon substrate SW.

The second inorganic layer IL2 may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. In one or more embodiments, the second inorganic layer IL2 may be formed of the same material as the above-described first inorganic layer IL1, but is not necessarily limited thereto. The second inorganic layer IL2 may be formed to have a thickness of around hundreds of microns, but is not necessarily limited thereto. The thickness of the second inorganic layer IL2 may be formed to be thicker than the thickness of the silicon substrate SW.

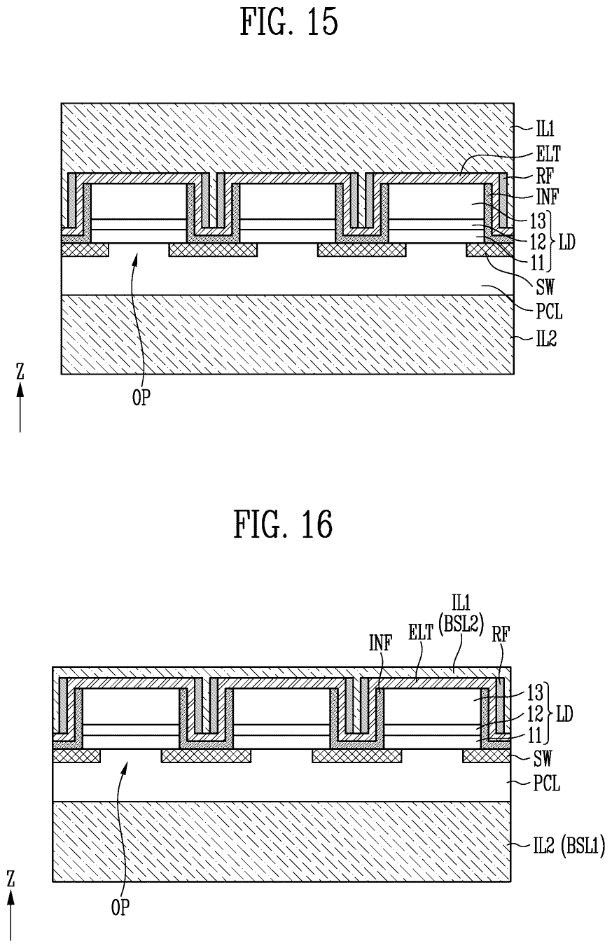

Referring to FIGS. 15 and 16, the first inorganic layer IL1 and the second inorganic layer IL2 are then inverted, and the first inorganic layer IL1 is ground down. The thickness of the first inorganic layer IL1 may be ground to be thinner than the thickness of the second inorganic layer IL2. The first inorganic layer IL1 may be formed to have a thickness of several microns, but is not necessarily limited thereto. Here, the thickness of the first inorganic layer IL1 may refer to a distance from the upper surface of the light-emitting element LD (or electrode layer ELT) to the upper surface of the first inorganic layer IL1.

The first inorganic layer IL1 may be formed between the light-emitting elements LD and on the light-emitting elements LD. For example, the first inorganic layer IL1 may cover the electrode layer ELT and/or the reflective layer RF. The first inorganic layer IL1 may be formed directly on the reflective layer RF located between the light-emitting elements LD. The first inorganic layer IL1 may be formed directly on the upper surface of the electrode layer ELT exposed by the reflective layer RF. The first inorganic layer IL1 of FIG. 16 may correspond to the second base layer BSL2 of FIG. 3, and the second inorganic layer IL2 of FIG. 16 may correspond to the first base layer BSL1 of FIG. 3.

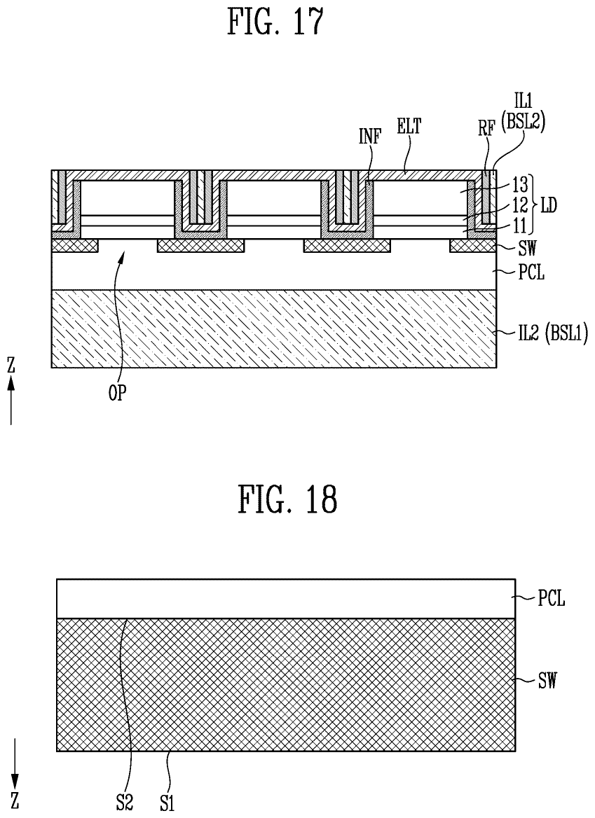

Referring to FIG. 17, the electrode layer ELT may be partially exposed in the step of grinding the first inorganic layer IL1. For example, the first inorganic layer IL1 may expose the electrode layer ELT exposed by the reflective layer RF. The first inorganic layer IL1 may be provided between the light-emitting elements LD. For example, the first inorganic layer IL1 may cover the reflective layer RF. The first inorganic layer IL1 may be formed directly on the reflective layer RF located between the light-emitting elements LD. The first inorganic layer IL1 of FIG. 17 may correspond to the second base layer BSL2 of FIG. 4, and the second inorganic layer IL2 of FIG. 17 may correspond to the first base layer BSL1 of FIG. 4.

According to the above, the light-emitting element LD and the circuit layer PCL may be formed using both surfaces of the silicon substrate SW, and the light-emitting element LD and the circuit layer PCL may be electrically connected through the opening OP of the silicon substrate SW. Accordingly, as described above, a bonding process for combining the light-emitting element LD and the circuit layer PCL can be omitted, thereby reducing costs, and simplifying the process.

Hereinafter, one or more other embodiments will be described. The same components as components described above will be referred to the same reference numerals in embodiments below, and redundant descriptions will be omitted or simplified.

FIGS. 18 to 24 are cross-sectional views illustrating process steps of a manufacturing method of a display device according to one or more embodiments. FIGS. 18 to 24 are cross-sectional views for illustrating the manufacturing method of the display device of FIG. 5, and are briefly shown and detailed symbols are omitted for convenience of description.

Referring to FIG. 18, first, a circuit layer PCL is formed on the second surface S2 of the silicon substrate SW. The silicon substrate SW may include a single crystalline silicon wafer, a polycrystalline silicon wafer, or an amorphous silicon wafer. The circuit layer PCL may include circuit elements including transistors that constitute the pixel circuit (PXC in FIG. 2) of each pixel PXL. For example, the circuit layer PCL may be formed of CMOS, which is a combination of NMOS and PMOS, but is not necessarily limited thereto.

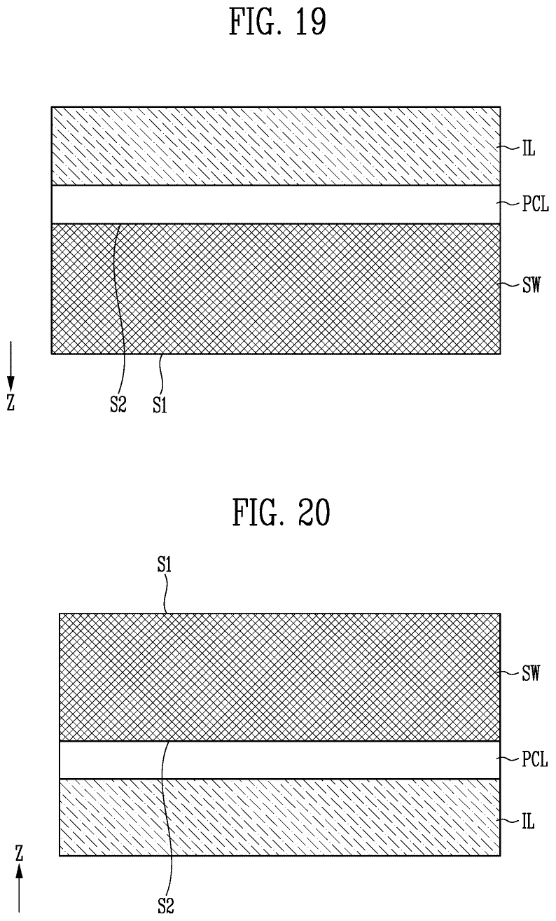

Referring to FIG. 19, an inorganic layer IL is then formed on the second surface S2 of the silicon substrate SW and the circuit layer PCL. The inorganic layer IL may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The inorganic layer IL may be formed to have a thickness of hundreds of microns, but is not necessarily limited thereto.

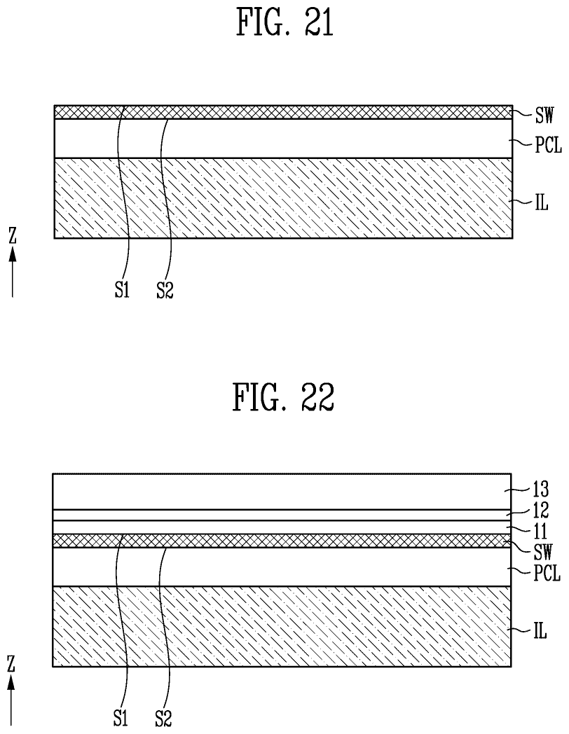

Referring to FIGS. 20 and 21, the silicon substrate SW and the inorganic layer IL are then inverted, and the first surface S1 of the silicon substrate SW is ground down. The thickness of the silicon substrate SW may be ground to be thinner than the thickness of the inorganic layer IL. The silicon substrate SW may be formed to have a thickness of several microns, but is not necessarily limited thereto.

Referring to FIG. 22, a light-emitting element layer (first semiconductor layer 11, active layer 12, and second semiconductor layer 13) is then formed on the first surface S1 of the silicon substrate SW. The first semiconductor layer 11, the active layer 12, and the second semiconductor layer 13 may be sequentially formed in the third direction (Z-axis direction) on the first surface S1 of the silicon substrate SW. The first semiconductor layer 11, the active layer 12, and the second semiconductor layer 13 may be formed by growing a seed crystal by an epitaxial method. According to one or more embodiments, the first semiconductor layer 11, the active layer 12, and the second semiconductor layer 13 may be formed by metal organic chemical vapor deposition (MOCVD). However, the present disclosure is not necessarily limited thereto, and the first semiconductor layer 11, the active layer 12, and the second semiconductor layer 13 may be formed by various methods, such as electron beam deposition, physical vapor deposition (PVD), chemical vapor deposition (CVD), plasma laser deposition (PLD), dual-type thermal evaporation, sputtering, and the like. Because the first semiconductor layer 11, the active layer 12, and the second semiconductor layer 13 have been described with reference to FIG. 5, redundant descriptions will be omitted.

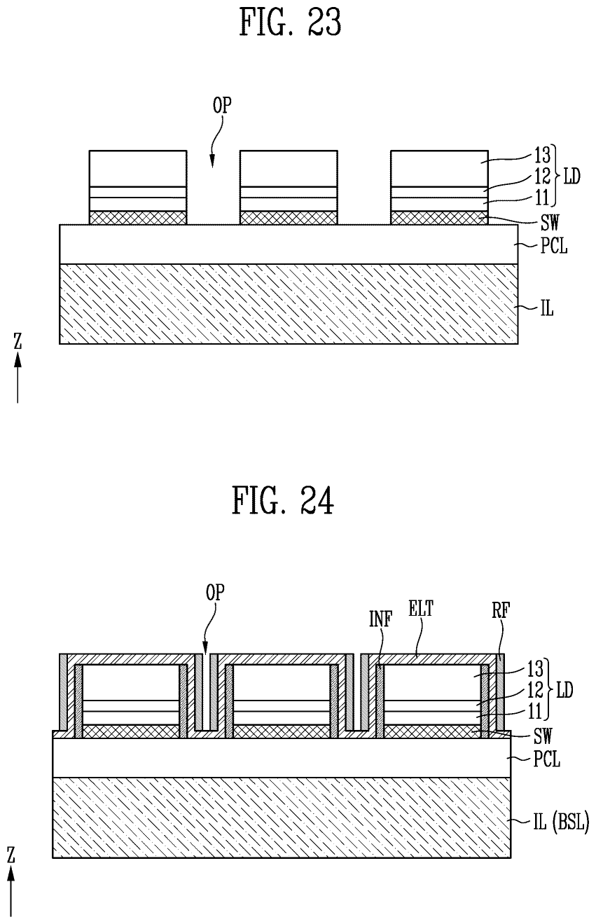

Referring to FIG. 23, the light-emitting element layer (first semiconductor layer 11, active layer 12, and second semiconductor layer 13) is then etched to form a light-emitting element LD. The etching process of the first semiconductor layer 11, the active layer 12, and the second semiconductor layer 13 is performed by dry etching, wet etching, reactive ion etching (RIE), inductively coupled plasma reactive ion etching (ICP-RIE), and the like, but is not necessarily limited thereto. While etching the first semiconductor layer 11, the active layer 12, and the second semiconductor layer 13, an opening OP may be formed in the silicon substrate SW. The opening OP of the silicon substrate SW may expose the circuit layer PCL.

Referring to FIG. 24, an insulating film INF, an electrode layer ELT, and/or a reflective layer RF are then formed on the light-emitting element LD. The insulating film INF may be partially formed on the side surfaces of the light-emitting elements LD. For example, after the insulating film INF is formed on the entire surface of the silicon substrate SW, it may be partially removed so that the circuit layer PCL exposed by the upper surface of the light-emitting elements LD and the opening OP of the silicon substrate SW may be exposed.

The electrode layer ELT may be formed on the light-emitting element LD, the insulating film INF, and the circuit layer PCL. The electrode layer ELT may be formed on the second semiconductor layer 13 of the light-emitting element LD exposed by the insulating film INF. The electrode layer ELT may directly contact the light-emitting element LD (or second semiconductor layer 13) exposed by the insulating film INF. The electrode layer ELT may be formed on the circuit layer PCL exposed by the opening OP of the silicon substrate SW. The electrode layer ELT may be directly contact the circuit layer PCL exposed through the opening OP of the silicon substrate SW.

The electrode layer ELT may be formed of transparent metal or transparent metal oxide. For example, the electrode layer ELT may be formed using at least one selected from indium tin oxide (ITO), indium zinc oxide (IZO), and zinc tin oxide (ZTO), but is not necessarily limited thereto.

According to one or more embodiments, a reflective layer RF may be further formed on the electrode layer ELT. The reflective layer RF may be partially formed on the side surface of the light-emitting element LD and/or the side surface of the electrode layer ELT. For example, the reflective layer RF may be formed on the entire surface of the silicon substrate SW, and then may be partially removed to expose the upper surface of the light-emitting elements LD and/or the upper surface of the electrode layer ELT. The material of the reflective layer RF is not particularly limited and may be formed of various reflective materials. The inorganic layer IL of FIG. 24 may correspond to the base layer BSL of FIG. 5.

According to the above, the light-emitting element LD and the circuit layer PCL may be formed using both surfaces of the silicon substrate SW, and the light-emitting element LD and the circuit layer PCL may be electrically connected through the opening OP of the silicon substrate SW. Accordingly, as described above, a bonding process for combining the light-emitting element LD and the circuit layer PCL can be omitted, thereby reducing costs and simplifying the process.

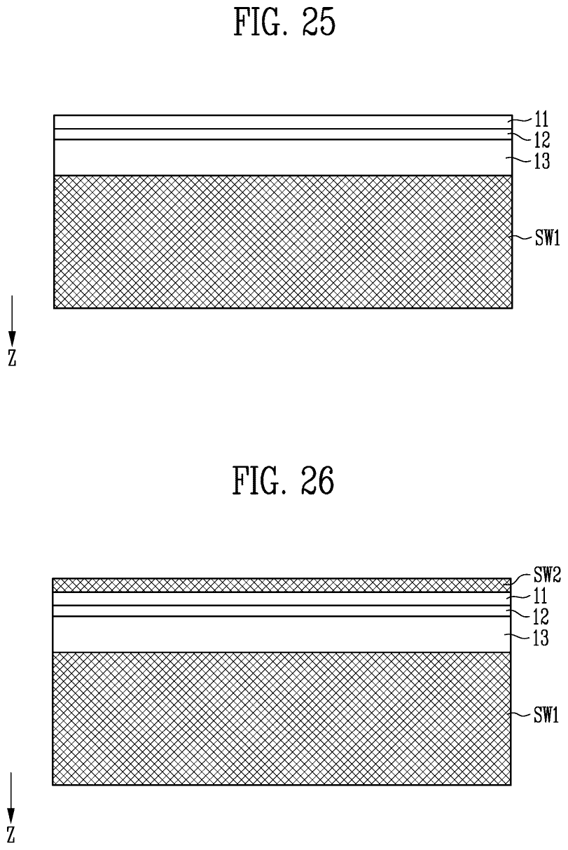

FIGS. 25 to 32 are cross-sectional views illustrating process steps of a manufacturing method of a display device according to one or more embodiments. FIGS. 25 to 32 are cross-sectional views for illustrating the manufacturing method of the display device of FIG. 6, and are briefly shown and detailed symbols are omitted for convenience of description.

Referring to FIG. 25, a light-emitting element layer (first semiconductor layer 11, active layer 12, and second semiconductor layer 13) is formed on the first silicon substrate SW1. The first silicon substrate SW1 may include a single crystalline silicon wafer, a polycrystalline silicon wafer, or an amorphous silicon wafer. The thickness of the first silicon substrate SW1 may be formed to have a thickness of hundreds of microns, but is not necessarily limited thereto.

The first semiconductor layer 11, the active layer 12, and the second semiconductor layer 13 may be formed by growing a seed crystal by an epitaxial method. According to one or more embodiments, the first semiconductor layer 11, the active layer 12, and the second semiconductor layer 13 may be formed by metal organic chemical vapor deposition (MOCVD). However, the present disclosure is not necessarily limited thereto, and the first semiconductor layer 11, the active layer 12, and the second semiconductor layer 13 may be formed by various methods, such as electron beam deposition, physical vapor deposition (PVD), chemical vapor deposition (CVD), plasma laser deposition (PLD), dual-type thermal evaporation, sputtering, and the like. Because the first semiconductor layer 11, the active layer 12, and the second semiconductor layer 13 have been described with reference to FIG. 6, redundant descriptions will be omitted.

Referring to FIG. 26, a second silicon substrate SW2 is then formed on the light-emitting element layer (first semiconductor layer 11, active layer 12, and second semiconductor layer 13). The second silicon substrate SW2 may be formed directly on the first semiconductor layer 11. The second silicon substrate SW2 may include a single crystalline silicon wafer, a polycrystalline silicon wafer, or an amorphous silicon wafer. The thickness of the second silicon substrate SW2 may be thinner than the thickness of the first silicon substrate SW1. For example, the second silicon substrate SW2 may be formed to have a thickness of several microns, but is not necessarily limited thereto.

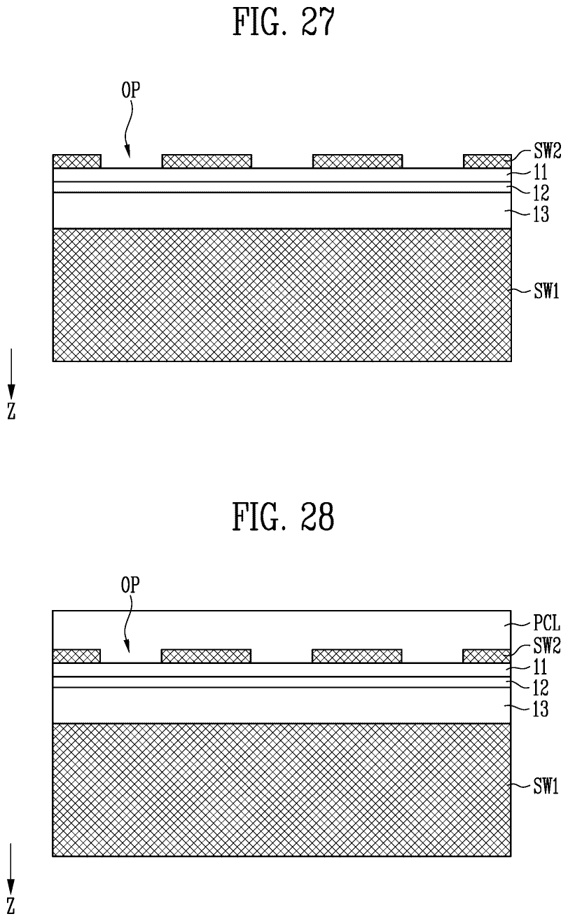

Referring to FIG. 27, the second silicon substrate SW2 is then etched to form an opening OP. The opening OP of the second silicon substrate SW2 may expose the first semiconductor layer 11 of the light-emitting element layer.

Referring to FIG. 28, a circuit layer PCL is then formed on the second silicon substrate SW2 and the light-emitting element layer (first semiconductor layer 11, active layer 12, and second semiconductor layer 13). The circuit layer PCL may include circuit elements including transistors that constitute the pixel circuit (PXC in FIG. 2) of each pixel PXL. For example, the circuit layer PCL may be formed of CMOS, which is a combination of NMOS and PMOS, but is not necessarily limited thereto. The circuit layer PCL may be electrically connected to the first semiconductor layer 11 of the light-emitting element layer through the opening OP of the second silicon substrate SW2. The circuit layer PCL may directly contact the first semiconductor layer 11 of the light-emitting element layer through the opening OP of the second silicon substrate SW2.

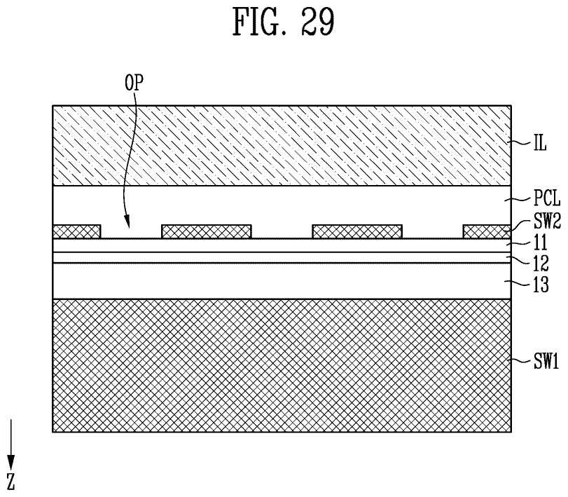

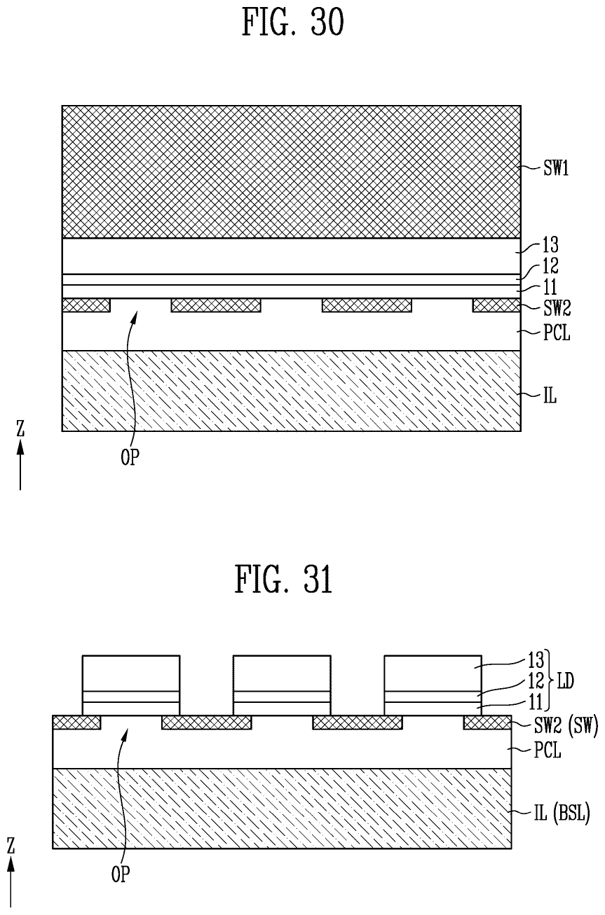

Referring to FIG. 29, an inorganic layer IL is then formed on the circuit layer PCL. The inorganic layer IL may include at least one selected from silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but is not necessarily limited thereto. The thickness of the inorganic layer IL may be formed to be thicker than the thickness of the second silicon substrate SW2. The inorganic layer IL may be formed to have a thickness of hundreds of microns, but is not necessarily limited thereto.

Referring to FIGS. 30 and 31, the first silicon substrate SW1 and the inorganic layer IL are then inverted. Next, the first silicon substrate SW1 is removed, and the first semiconductor layer 11, the active layer 12, and the second semiconductor layer 13 are etched to form the light-emitting element LD. The etching process of the first semiconductor layer 11, the active layer 12, and the second semiconductor layer 13 includes dry etching, wet etching, and reactive ion etching (RIE), inductively coupled plasma reactive ion etching (ICP-RIE), etc., but is not necessarily limited thereto.

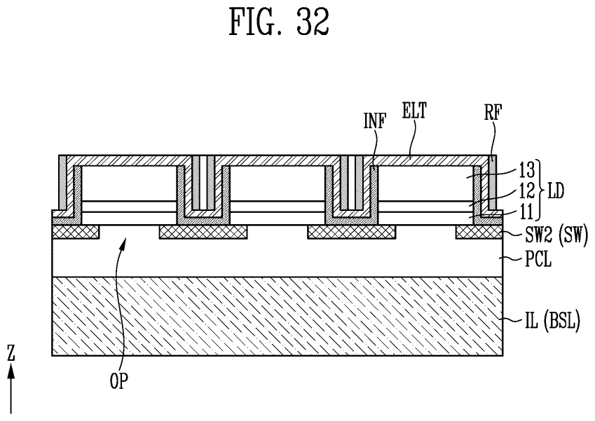

Referring to FIG. 32, an insulating film INF, an electrode layer ELT, and/or a reflective layer RF are then formed on the light-emitting element LD. The insulating film INF may be partially formed on the side surfaces of the light-emitting elements LD. For example, the insulating film INF may be formed on the entire surface of the silicon substrate SW and then partially removed to expose the upper surface of the light-emitting elements LD.

The electrode layer ELT may be formed on the light-emitting element LD and the insulating film INF. The electrode layer ELT may be formed on the second semiconductor layer 13 of the light-emitting element LD exposed by the insulating film INF. The electrode layer ELT may directly contact the light-emitting element LD (or second semiconductor layer 13) exposed by the insulating film INF. The electrode layer ELT may be formed of transparent metal or transparent metal oxide. For example, the electrode layer ELT may be formed using at least one selected from indium tin oxide (ITO), indium zinc oxide (IZO), and zinc tin oxide (ZTO), but is not necessarily limited thereto.

According to one or more embodiments, a reflective layer RF may be further formed on the electrode layer ELT. The reflective layer RF may be partially formed on the side surface of the light-emitting element LD and/or the side surface of the electrode layer ELT. For example, the reflective layer RF may be formed on the entire surface of the silicon substrate SW, and then may be partially removed to expose the upper surface of the light-emitting elements LD and/or the upper surface of the electrode layer ELT. The material of the reflective layer RF is not particularly limited, and may be formed of various reflective materials. The inorganic layer IL of FIG. 32 may correspond to the base layer BSL of FIG. 6, and the second silicon substrate SW2 of FIG. 32 may correspond to the silicon substrate SW of FIG. 6.

According to the above, the light-emitting element LD and the circuit layer PCL may be formed using both surfaces of the second silicon substrate SW2, and the light-emitting element LD and the circuit layer PCL may be electrically connected through the opening OP of the second silicon substrate SW2. Accordingly, as described above, a bonding process for combining the light-emitting element LD and the circuit layer PCL can be omitted, thereby reducing costs and simplifying the process.

A person of ordinary skill in the art related to the present disclosure will understand that it can be implemented in a modified form within a range that does not deviate from the essential characteristics of the above description. Therefore, the disclosed methods are to be considered in an illustrative sense rather than a restrictive sense. The scope of the present disclosure is indicated in the claims rather than the foregoing description, and all differences within an equivalent scope should be construed as being included in the present disclosure.

What is claimed is:

1. A display device comprising:
a first base layer;
a circuit layer above the first base layer;
a silicon substrate above the circuit layer;
a light-emitting element above the silicon substrate, and electrically connected to the circuit layer through an opening defined by the silicon substrate; and
a second base layer above the silicon substrate and the light-emitting element.

2. The display device of claim 1, wherein a thickness of the first base layer is greater than a thickness of the silicon substrate.

3. The display device of claim 2, wherein the thickness of the first base layer is greater than a thickness of the second base layer.

4. The display device of claim 3, wherein the second base layer comprises a transparent inorganic material.

5. The display device of claim 4, wherein the first base layer and the second base layer comprise a same material.

6. The display device of claim 5, wherein the light-emitting element comprises:
a first semiconductor layer above the silicon substrate;
an active layer above the first semiconductor layer; and
a second semiconductor layer above the active layer.

7. The display device of claim 6, further comprising an electrode layer above the second semiconductor layer, and covered by the second base layer.

8. The display device of claim 6, further comprising an electrode layer above the second semiconductor layer, and exposed by the second base layer.

9. The display device of claim 8, wherein an opening defined by the silicon substrate exposes the first semiconductor layer.

10. A manufacturing method of a display device, the method comprising:
forming a light-emitting element above a first surface of a silicon substrate;
forming a first inorganic layer above the first surface of the silicon substrate and the light-emitting element;
grinding a second surface of the silicon substrate;
forming an opening by etching the silicon substrate;
forming a circuit layer above the second surface of the silicon substrate and the light-emitting element; and
forming a second inorganic layer above the circuit layer.

11. The manufacturing method of claim 10, wherein the opening of the silicon substrate exposes the light-emitting element.

12. The manufacturing method of claim 11, wherein the circuit layer contacts the light-emitting element through the opening of the silicon substrate.

13. The manufacturing method of claim 12, wherein a thickness of the silicon substrate is less than a thickness of the second inorganic layer.

14. The manufacturing method of claim 13, further comprising grinding the first inorganic layer.

15. The manufacturing method of claim 14, wherein a thickness of the first inorganic layer is less than the thickness of the second inorganic layer.

16. The manufacturing method of claim 15, wherein the first inorganic layer and the second inorganic layer comprise a same material.

17. A manufacturing method of a display device, the method comprising:
forming a light-emitting element layer above a first silicon substrate;
forming a second silicon substrate above the light-emitting element layer;
forming an opening by etching the second silicon substrate;
forming a circuit layer above the second silicon substrate and the light-emitting element layer;
forming an inorganic layer above the circuit layer;
removing the first silicon substrate; and
forming a light-emitting element by etching the light-emitting element layer.

18. The manufacturing method of claim 17, wherein the opening of the second silicon substrate exposes the light-emitting element layer.

19. The manufacturing method of claim 18, wherein the circuit layer contacts the light-emitting element layer through the opening of the second silicon substrate.

20. The manufacturing method of claim 19, wherein a thickness of the second silicon substrate is less than a thickness of the inorganic layer.
